(19) United States
(12) Patent Application Publication
(10) Pub. No.: US 2013/0284514 A1
(43) Pub. Date: Oct. 31, 2013

(54) TERMINAL BOX FOR SOLAR CELL MODULE

(71) Applicant: SUMITOMO WIRING SYSTEMS, LTD., Yokkaichi-City (JP)

(72) Inventors: Tomoya Kawaguchi, Yokkaichi-City (JP); Takahiro Asao, Yokkaichi-City (JP)

(73) Assignee: SUMITOMO WIRING SYSTEMS, LTD., Yokkaichi-City (JP)

(21) Appl. No.: 13/752,430

(22) Filed: Jan. 29, 2013

(30) Foreign Application Priority Data
Apr. 26, 2012 (JP) 2012-101190

(51) Int. Cl. H05K 5/02

(52) U.S. Cl. CPC H05K 5/0247
USPC 174/565

(57) ABSTRACT

A terminal (20) formed of an electrically conductive plate member is accommodated into a box (11). The terminal (20) includes a cable connecting portion (26) to be connected to a cable (80) and a cell-side connecting portion (27) located at an extending leading end portion (32) extending from the cable connecting portion (26), located outside the box (11) and insertable into a housing (91) through an opening (98) formed in the housing (91) to be connected to an electrode of solar cells (95) in the housing (91).

### BACKGROUND OF THE INVENTION

1. Field of the Invention

The invention relates to a terminal box for solar cell module.

2. Description of the Related Art

Japanese Unexamined Patent Publication No. 2007-311665 discloses terminal box for solar cell module that includes a box made of resin that is to be mounted on a housing of a solar cell module. Output wires connected to electrodes of solar cells are arranged in the housing and two cables for external connection have end parts introduced into the box. Terminals in the box have cable connecting portions to be connected to the cables and a cell-side connecting portions connected to the output wires. The output wires are drawn into the box in the process of mounting the box to the housing and are soldered into connection with the cell-side connecting portions of the terminals. This conventional configuration requires the difficult operation of connecting the output wires to the terminals while the box is held facing a mounting surface of the solar cell module.

FIG. 17 shows a condensing and tracking solar cell module with a hollow housing 1. A box 2 is mounted on a side surface of the housing 1 and, a sealing material 5, such as silicon resin, is poured into the box 2 to seal a connecting part of a terminal 3 and an output wire 4. The poured sealing material 5 flows into the housing 1 through an opening 6 perforated in the housing 1. Thus, there is a problem that the interior of the housing 1 may not be sealed properly with resin.

FIG. 18 attempts to address the above-described problem by inserting a cable 8 through a grommet 7 and into the housing 1. The grommet 7 then is fit into the opening 6 of the housing 1 without using a terminal box. The output wire 4 then is connected directly to a leading end of the cable 8. This method avoids performing a connecting operation while the box is held and avoids pouring the sealing material. However, the cable 8 has a considerable resilient reaction force and may be difficult to lay in the housing 1. Further, the grommet 7 may deform as the cable 8 is bent in the housing 1, and may not provide a predetermined sealing property.

The invention was completed based on the above situation and an object thereof is to enable a terminal box to be mounted on a housing of a solar cell module without any problem.

### SUMMARY OF THE INVENTION

The invention is directed to a terminal box for solar cell module, comprising a box that is made of resin and is to be mounted on a housing of a solar cell module. A cable for external connection has an end part introduced into the box. A terminal formed from an electrically conductive plate is accommodated in the box. The terminal has a cable connecting portion to be connected to the cable and a cell-side connecting portion at an extending leading end portion extending from the cable connecting portion. The, cell-side connecting portion is insertable into the housing through an opening and is to be connected to an electrode of solar cells in the housing. The electrode of the solar cells can be connected to the cell-side connecting portion of the terminal in the housing while the box is mounted on the housing of the solar cell module. Thus, there is no need to hold the box while the cell-side connecting portion is being connected and no need to seal the interior of the box with a sealing material. Further, the connecting operation in the housing is not difficult. As a result, the terminal box can be mounted on the housing of the solar cell module without any problem.

The terminal box preferably has an insulating portion located between the terminal and the housing in the opening when being mounted on the housing. The insulating portion enables the housing and the terminal to be held in an insulated state, thereby avoiding a situation where the terminal is shorted mistakenly to the housing, if the housing is made of metal.

The insulating portion preferably has a positioning structure that can be fit into the opening for positioning the box with respect to the housing and holding the box on the housing.

The terminal box preferably comprises a plus-side terminal box with a conductor that is to be connected to a plus-side electrode of the solar cells and a minus-side terminal box with a conductor that is to be connected to a minus-side electrode of the solar cells. The plus-side terminal box and the minus-side terminal box preferably are provided independently. Thus, the terminal box can accommodated a situation where the plus-side and minus-side electrodes are spaced apart due to an arrangement pattern of the solar cells and enhances versatility.

The plus-side terminal box preferably has a plus-side identifying portion and the minus-side terminal box includes a minus-side identifying portion. The plus-side identifying portion is engaged with a plus-side identification receiving portion of the housing, but does not engage with a minus-side identification receiving portion of the housing when the plus-side terminal box is mounted on the housing. The minus-side identifying portion is engaged with the minus-side identification receiving portion of the housing, but does not engage with the plus-side identification receiving portion of the housing when the minus-side terminal box is mounted on the housing. Accordingly, the plus-side terminal box cannot connect to the minus-side electrode by mistake and the minus-side terminal box cannot connect to the plus-side electrode by mistake.

The box preferably is mounted on a side surface intersecting a light receiving surface of the housing. Accordingly, shape stability during transportation is excellent unlike a situation where the box is mounted on a surface opposite to the light receiving surface of the housing.

The cable preferably is laid along the side surface of the housing to prevent a situation where the cable gets entangled with an external matter.

The box preferably has a box main body into which an end part of the cable and the terminal are to be accommodated and a cover to be mounted on the box main body to close an opening of the box main body. The cover is provided integrally with a fixing portion for contacting and fixing the cable as the cover is mounted on the box main body. The fixing portion on the cover avoids the need to provide a dedicated fixing member for fixing the cable. Thus, the configuration can be simplified and the number of parts can be reduced.

### BRIEF DESCRIPTION OF THE DRAWINGS

FIG. 1 is a side view in section showing a state where a box is mounted on a side surface of a housing and a lead wire of solar cells is connected to a cell-side connecting portion of a terminal in the housing in a terminal box for solar cell module according to a first embodiment of the invention.

FIG. 2 is an enlarged plan view in section showing an essential part of FIG. 1.

FIG. 3 is a front view showing a state where an end part of a cable is connected to a cable connecting portion of the terminal before a cover is mounted.

FIG. 4 is a plan view of the terminal box for solar cell module.

FIG. 5 is a front view of the terminal box for solar cell module.

FIG. 6 is a plan view in section of the terminal box for solar cell module.

FIG. 7 is a rear view of the cover.

FIG. 8 is a side view of the cover.

FIG. 9 is a rear view of a plus-side terminal box.

FIG. 10 is a rear view of a minus-side terminal box.

FIG. 11 is an exploded perspective view of the solar cell module showing a housing main body having boxes mounted on opposite side surfaces and a condensing plate.

FIG. 12 is a perspective view showing a plurality of connected solar cell modules.

FIG. 13 is a perspective view, partly cut away, of the solar cell module.

FIG. 14 is a front view of a plus-side terminal box and a plus-side identification receiving portion corresponding to a plus-side identifying portion in the plus-side terminal box in a terminal box for solar cell module according to a second embodiment.

FIG. 15 is a front view of a minus-side terminal box and a minus-side identification receiving portion corresponding to a minus-side identifying portion in the minus-side terminal box.

FIG. 16 is a plan view of the plus-side terminal box.

FIG. 17 is a side view in section of a first reference solar cell module.

FIG. 18 is a side view in section of a second reference solar cell module.

### DETAILED DESCRIPTION OF THE PREFERRED EMBODIMENTS

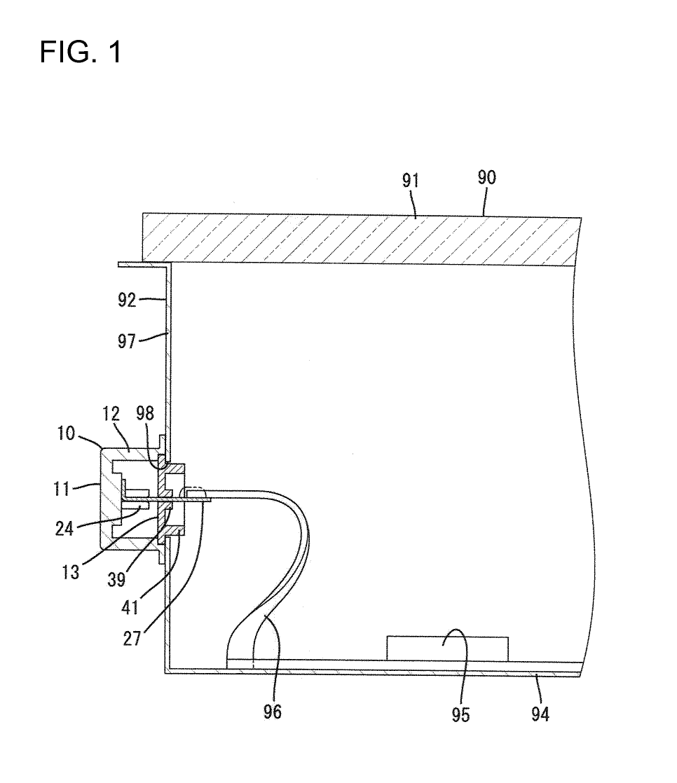

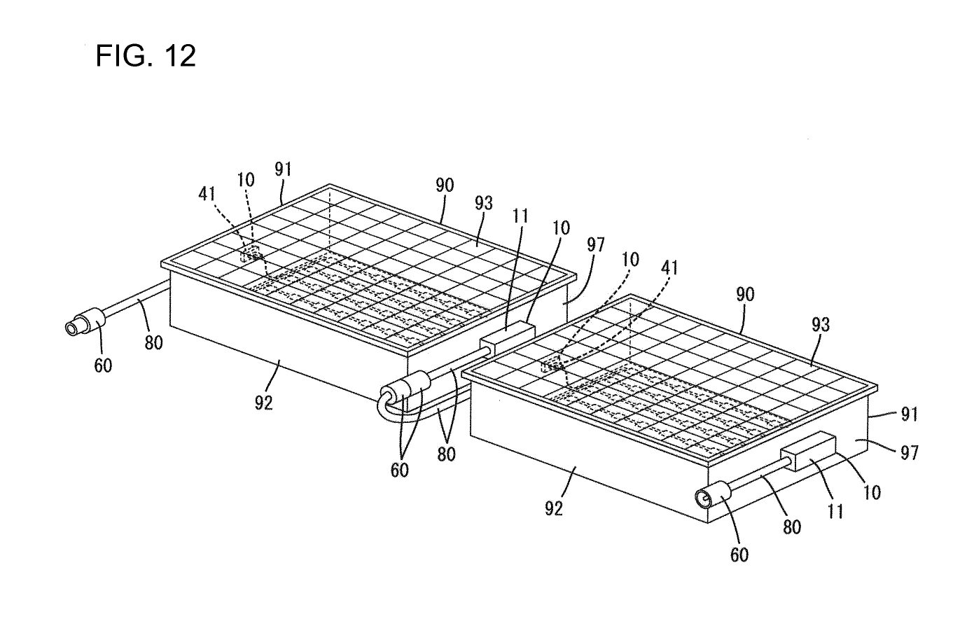

A first embodiment of the invention is described with reference to FIGS. 1 to 13. A terminal box 10 for solar cell module according to the first embodiment is mounted on a housing 91 of a solar cell module 90 as shown in FIG. 12.

The first embodiment illustrates a condensing and tracking power generation system with a planar array of solar cell modules 90 supported on an unillustrated mount. The mount follows the sun's movement so that a condensing plate 93 on a surface of the mount always faces the sun.

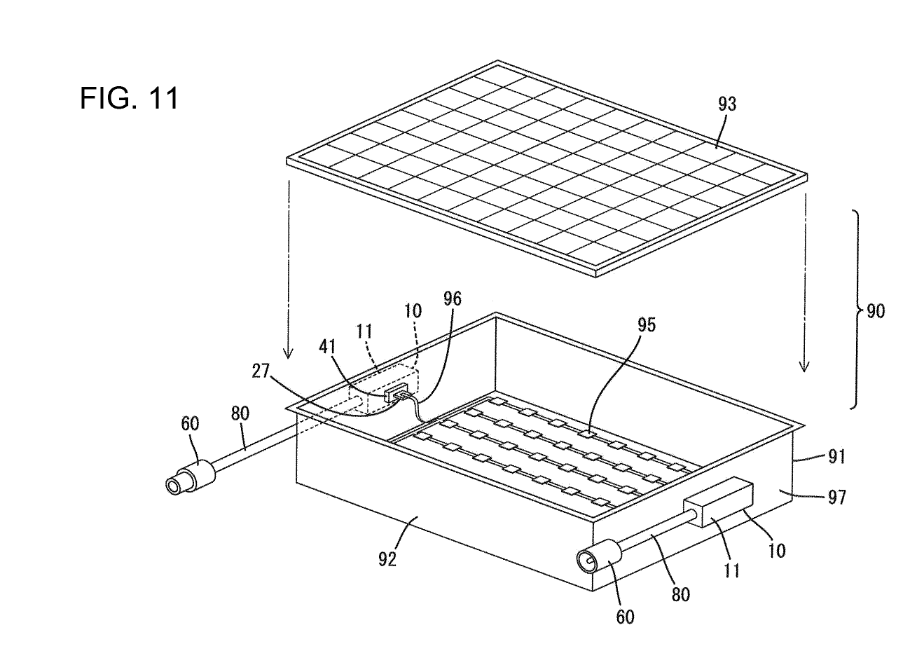

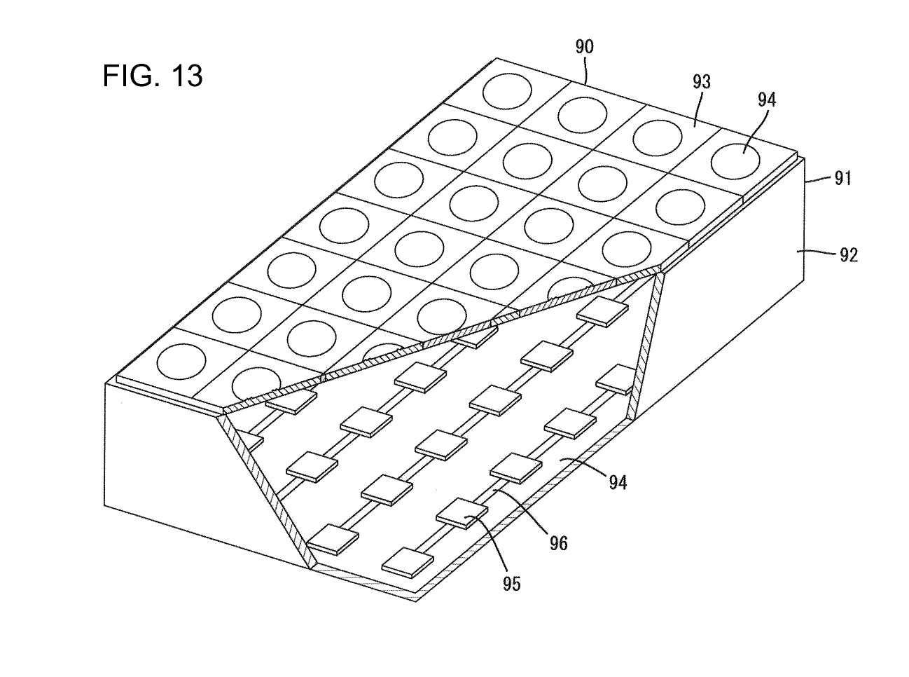

The solar cell module 90 has a rectangular box-shaped metal housing 91 with a housing main body 92 that has an upper opening, as shown in FIG. 13. The condensing plate 93 to be mounted on the upper end of the housing main body 93 to close the opening and the hollow interior thereof. The condensing plate 93 includes condenser lenses 93a, such as Fresnel lenses, for condensing sunlight. The housing main body 92 includes a supporting plate 94 at a position facing the condensing plate 93 and a plurality of solar cells 95 are arranged on the supporting plate 94. The solar cells 95 are arranged in an array at positions for receiving the sunlight condensed by the respective condenser lenses 93a. Lead wires 96 are connected to electrodes of the respective solar cells 95. As shown in FIG. 11, the lead wires 96 connected to plus-side and minus-side electrodes of the solar cells 95 located at both front and rear ends are drawn out to be substantially free to bend, and are connectable to terminals 20 of the terminal boxes 10 as described below.

Side plates 97 stand from the outer peripheral edge of the supporting plates 94 so that outer surfaces of the side plates 97 are substantially perpendicular to surfaces of the condensing plate 93. As shown in FIG. 1, each side plate 97 has a substantially rectangular opening 98 and the terminals 10 are fit in each of the both openings 98. As shown in FIG. 12, cables 80 extend from the terminal boxes 10 and are connected via connectors 60 between the solar cell modules 90 to connect the solar cell modules 90 are to each other.

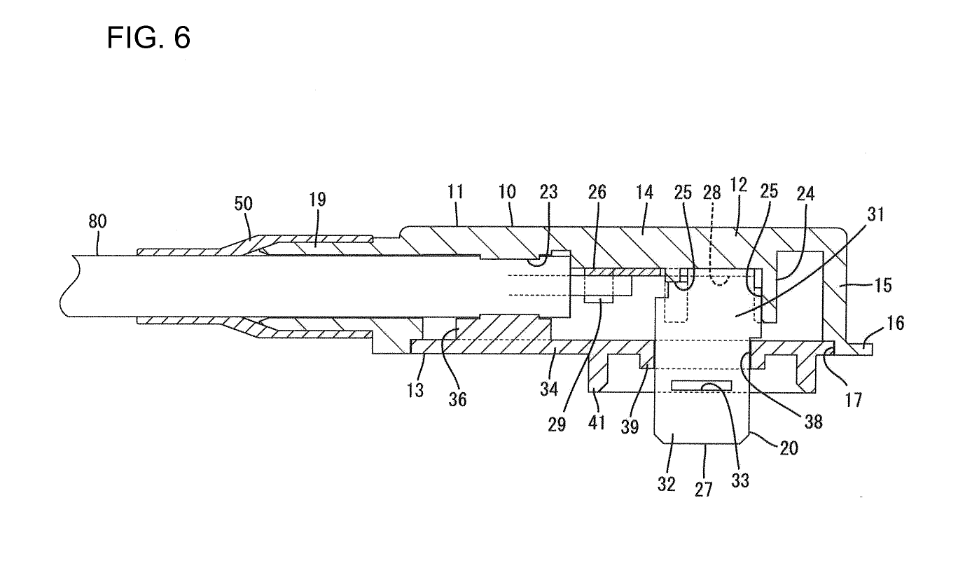

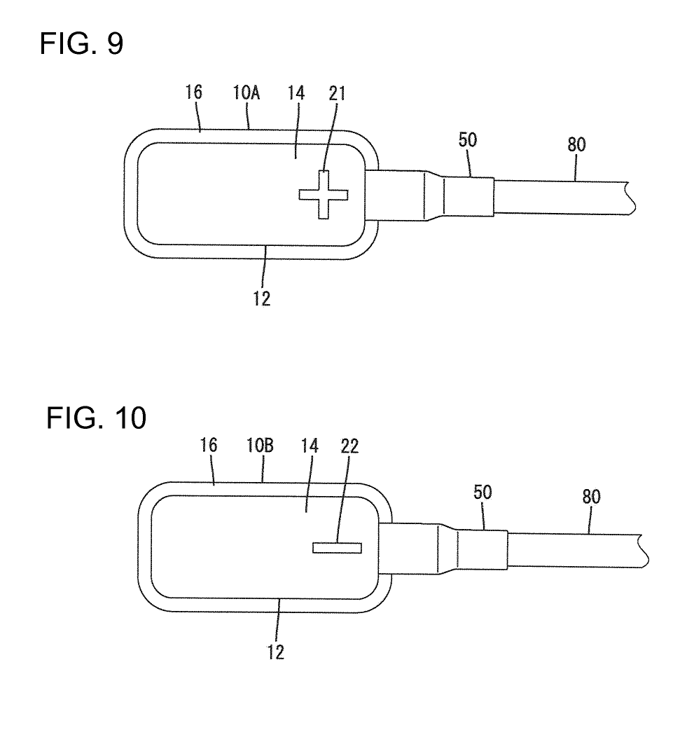

As shown in FIG. 6, the terminal box 10 includes a box 11, a terminal 20 accommodated in the box 11 and the cable 80. The cable 80 is drawn out from the box 11, but an end of the cable 80 accommodated in the box 11. The terminal box 10 comprises a plus-side terminal box 10A (see FIG. 9) connected to the lead wires 96 extending from positive electrodes of the solar cells 95 and a minus-side terminal box 10B (see FIG. 10) connected to the lead wires 96 extending from negative electrodes of the solar cells 95. The plus-side terminal box 10A and the minus-side terminal box 10B are separate bodies provided independently of each other.

The box 11 is made of synthetic resin and has a box main body 12 with a front opening and a cover 13 to close the front opening.

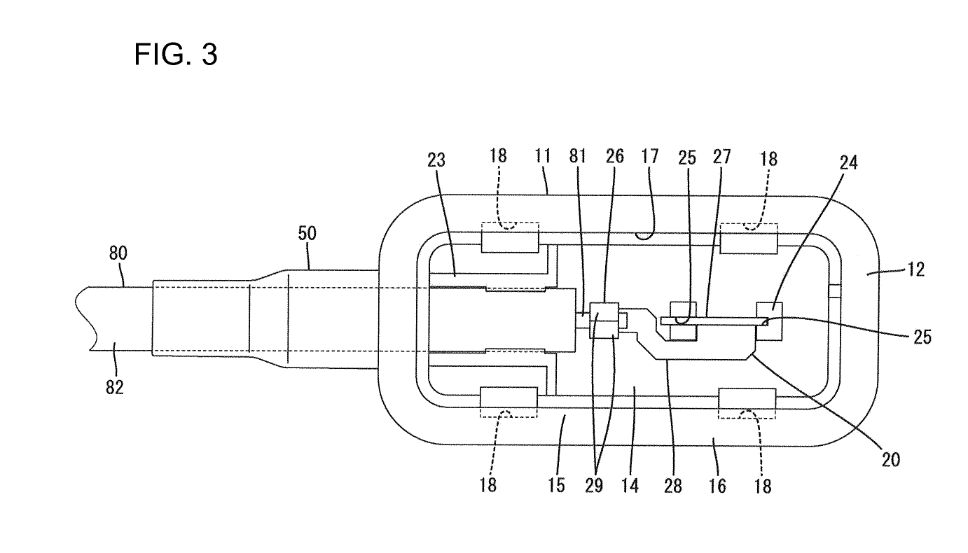

The box main body 12 is a long narrow cap with a substantially rectangular mounting plate 14 and a tubular peripheral wall 15 projecting from the outer periphery of the mounting plate 14. The terminal 20 and the cable 80 are mounted on the mounting plate 14. As shown in FIG. 3, the cable 80 has a core 81 made of plural strands covered by an insulation coating 82. The insulation coating 82 is stripped at an end of the cable 80 to expose the core 81.

As shown in FIGS. 3 and 6, a flange 16 bulges out at the front end of the peripheral wall 15 and a step 17 is formed over the entire inner periphery of the front end of the peripheral wall 15 to define a recess. An outer part of the cover 13 is mounted in this recess.

Two spaced apart engaging recesses 18 open forwardly and inwardly on each of longer sides of the peripheral wall 15. Locks 35 on the cover 13 can engage in the engaging recesses 18 to fix the cover 13 to the box main body 12.

As shown in FIG. 6, a tubular portion 19 projects sideways from one shorter side of the peripheral wall 15 and receives the cable 80. A rubber boot 50 is fit over the tubular portion 19 and the cable 80 to prevent water from entering the box 11 through a clearance between the cable 80 and the tubular portion 19.

A “+” sign 21 is indented on the rear surface of the mounting plate 14 of the plus-side terminal box 10A, as shown in FIG. 9, and a “−” sign 22 is indented on the rear surface of the mounting plate 14 of the minus-side terminal box 10A, as shown in FIG. 10. The signs 21, 22 visually identify the plus-side terminal box 10A and the minus-side terminal box 10B.

As shown in FIGS. 3 and 6, a cable receiving portion 23 is formed on the front surface of the mounting plate 14 at the end of the box main body 12 where the cable 80 is drawn out to position and support the end part of the cable 80. A terminal receiving portion 24 projects from the front surface of the mounting plate 14 at the end of the box main body 12 opposite the cable receiving portion 23 for receiving the end part of the terminal 20. The terminal receiving portion 24 has insertion grooves 25 for receiving the terminal 20. The insertion grooves 25 are in the form of slits deep in forward and backward directions and extending in the width direction.

The terminal 20 is formed integrally by bending an electrically conductive metal plate and includes a cable connecting portion 26, a cell-side connecting portion 27 and a coupling 28 that couples the cell-side connecting portion 27 and the cable connecting portion 26, as shown in FIGS. 3 and 6. The cable connecting portion 26 includes two crimping pieces 29 that are crimped and connected to the core 81 and wrap around the core 81. As shown in FIG. 3, the coupling 28 is on the same plane as the bottom surface of the cable connecting portion 26 and has a substantially crank shape extending from the cable connecting portion 26 to the cell-side connecting portion 27 when viewed from the front. The cable connecting portion 26 is adjacent an end of the cable receiving portion 23 when the terminal 20 is mounted in the terminal receiving portion 24, and the coupling 28 is adjacent to and comes around the terminal receiving portion 24.

The cell-side connecting portion 27 is wider than the cable connecting portion 26 and the coupling 28 and has a plate surface substantially perpendicular to the cable connecting portion 26 and the coupling 28. That is, the cell-side connecting portion 27 is bent substantially at a right angle from an end part of the coupling 28.

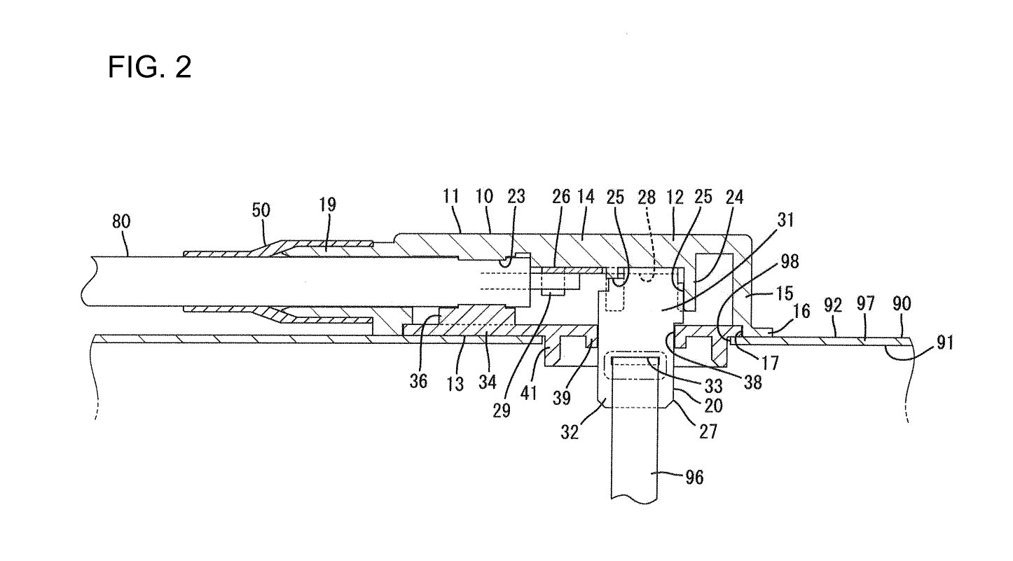

Both sides of the cell-side connecting portion 27 are held in contact with the surfaces of the insertion grooves 25 to position and support the terminal 20 in the terminal receiving portion 24. As shown in FIG. 6, the cell-side connecting portion 27 projects in forward and backward directions, which are substantially perpendicular to the surface of the mounting plate 14, and the coupling 28 and the cable connecting portion 26 are arranged substantially along the surface of the mounting plate 14. A base end 31 of the cell-side connecting portion 27 close to the coupling 28 is accommodated in the box main body 12 and within the standing range of the peripheral wall 15, whereas a leading end 32 distant from the coupling 28 is exposed outside of the box main body 12 and beyond the standing range of the peripheral wall 15. A slit-like connection hole 33 is formed in the cell-side connecting portion 27 near the leading end 32 and extends in the width direction. As shown in FIG. 2, the cell-side connecting portion 27 is in the housing 91 when the terminal box 10 is mounted on the side surface of the housing 91 and the lead wire 96 is soldered to the connection hole 33 of the cell-side connecting portion 27 in the housing 91.

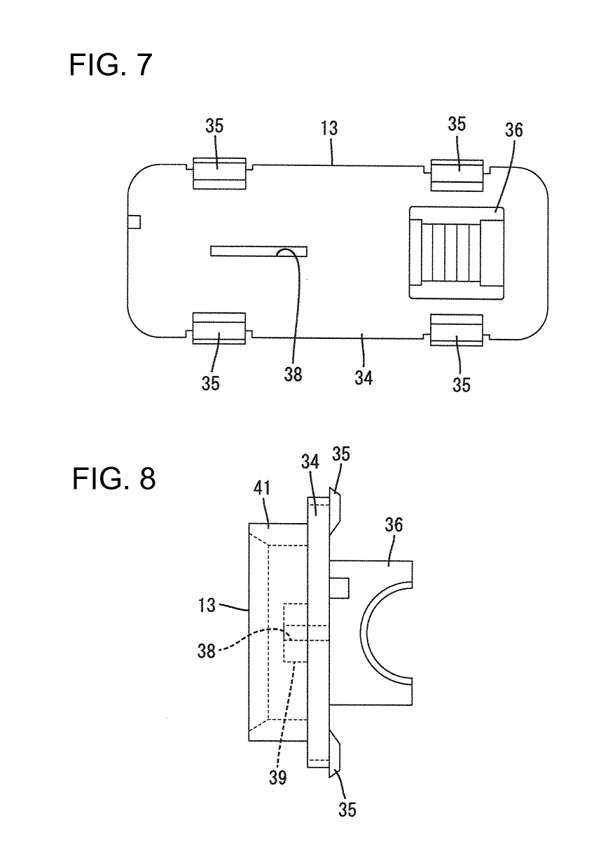

As shown in FIG. 5, the cover 13 includes a substantially rectangular cover main body 34 extending along the step 17 of the peripheral plate 15. As shown in FIG. 7, two spaced-apart locks 35 project from each of the longer side edges of the cover main body 34. Each lock 35 is in the form of a claw that resiliently engages the corresponding engaging portion 18 from the inner side when the cover 13 is fixed.

A fixing portion 36 projects integrally from the rear surface of the cover main body 34 at a position facing the cable receiving portion 23. As shown in FIG. 8, the fixing portion 36 has an arcuate inner surface that can be arranged along the outer peripheral surface of the cable 80. Thus, the end part of the cable 80 is sandwiched fixedly between the fixing portion 36 and the cable receiving portion 23 when the cover 13 is fixed, as shown in FIG. 6.

As shown in FIG. 7, a slit-like through hole 38 is formed on the end of the cover main body 34 opposite the fixing portion 36 and extends in the long direction of the cover 13. The cell-side connecting portion 27 is inserted tightly into the through hole 38 when the cover 13 is fixed so that the extending leading end 32 projects forward from the through hole 38.

As shown in FIGS. 5 and 6, a thick portion 39 projects in a stepped manner from the front surface of the cover main body 34 at the periphery of the through hole 38. The thick portion 39 makes an extending range of the through hole 38 equal to or larger than the plate thickness of the end of the cover main body 34.

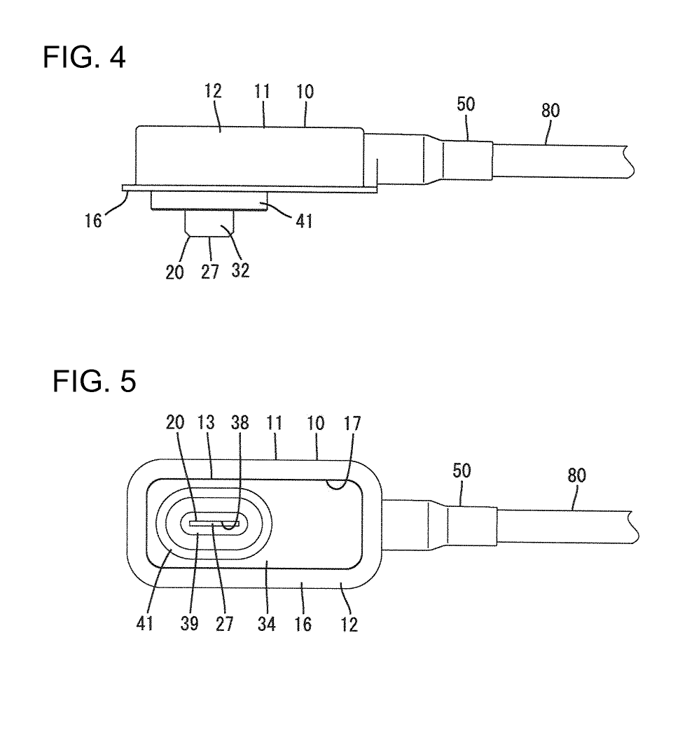

A tubular insulating portion 41 surrounds the thick portion 39 over the entire periphery on the front surface of the cover main body 34. As shown in FIG. 2, the insulating portion 41 is fit tightly into the opening 98 of the housing 91 and is held in the opening 98 when mounted on the housing 91. The insulating portion 41 projects farther than that of the thick portion 29 and the plate thickness of the side plate 97. The front end of the cell-side connecting portion 27 is before the front end of the insulating portion 41 when the cover 13 is fixed, but the connection hole 33 of the cell-side connecting portion 27 is behind the front end of the insulating portion 41 and is concealed within the insulating portion 41 when viewed from above, as shown in FIG. 4.

The terminal box 10 is assembled by inserting the terminal 20 into the terminal receiving portion 24 of the box main body 12 from the front. The coupling 28 and the cable connecting portion 26 are placed on the front surface of the mounting plate 14 and the cell-side connecting portion 27 projects forward. The end part of the cable 80 then is inserted sideways into the tubular portion 19 so that the cable 80 enters the box main body 12 and is supported in the cable receiving portion 23. Further, the core 81 of the cable 80 is placed on the cable connecting portion 26 and the crimping pieces 29 are crimped and connected to the core 81, as shown in FIG. 3.

The cover 13 then is fit into the step 17 of the box main body 12. In the process of mounting the cover 13, the cell-side connecting portion 27 of the terminal 20 is inserted into the through hole 38 of the cover main body 34 from behind so that the extending leading end 32 of the cell-side connecting portion 27 projects forward from the through hole 38. The cable 80 is fixed between the fixing portion 36 and the cable receiving portion 23 and the locks 35 resiliently engage the corresponding engaging portions 18 to fix the cover 13 to the box main body 12 at a proper mounting position. In this way, the terminal box 10 is assembled with the cable 80 extending in a length direction of the terminal box 10, as shown in FIGS. 4 to 6. Further, the front surface of the terminal box 10 from the cover 13 to the box main body 12 is substantially planar and continuous.

A fixing material, such as adhesive, is applied to the front surface of the terminal box 10. The insulating portion 41 of the box 11 then is fit into the opening 98 of the housing main body 92, as shown in FIGS. 1 and 2, so that the fixing material fixes the terminal box 10 on the side surface of the housing main body 92. Further, the cable 80 drawn out from the terminal box 10 extends laterally along the side surface of the housing main body 92, as shown in FIG. 11.

The extending leading end 32 of the cell-side connecting portion 27 projects into the housing main body 92 as the insulating portion 41 is fit into the opening 98 of the housing main body 92. At this time, the cell-side connecting portion 27 is at a position substantially facing the lead wire 96 in the housing 91. Note that the plus-side terminal box 10A and the minus-side terminal box 10B are mounted respectively in the front and rear openings 98 on the side surfaces of the housing main body 92 while being spaced apart.

The leading end part of the lead wire 96 then is soldered in the connection hole 33 of the cell-side connecting portion 27. This solder connection operation can be performed in the housing main body 92. The condensing plate 93 then is mounted on the upper end of the housing main body 92. Further, the connectors 60 are connected to the extending ends of the respective plus-side and minus-side cables 80 extending from the side surfaces of the housing 91 and, as shown in FIG. 12, the respective solar cell modules 90 are connected in series by connecting the connectors 60 to the connectors 60 of adjacent solar cell modules 90.

As described above, the electrodes (including the lead wires 96) of the solar cells 95 can be connected to the cell-side connecting portions 27 of the terminals 20 inserted in the housing 91 while the boxes 11 are mounted on the housing 91 of the solar cell module 90. Thus, the boxes 11 need not be held while the cell-side connecting portions 27 are being connected and the interior of the boxes 11 need not be sealed with a sealing material. Further, unlike the cables 80, the connecting operation in the housing 91 is not difficult. As a result, the terminal boxes 10 can be mounted on the housing 91 of the solar cell module 90 without any problem.

The box 11 insulating portion 41 of the box 11 is between the terminal 20 and the housing 91 in the opening 98 when the box 11 is mounted on the housing 91 to ensure that the terminal 20 is not be shorted mistakenly to the housing 91. The insulating portion 41 also efficiently positions the box 11 with respect to the housing 91 while being fit into the opening 98.

The plus-side and minus-side terminal boxes 10A and 10B are independent so that an arrangement pattern of the solar cells 95 can be dealt with flexibly with enhanced versatility.

The box 11 is mounted on the side surface intersecting a light receiving surface of the condensing plate 93 of the housing 91. Thus, shape stability during transportation is excellent, unlike a case where the box 11 is mounted on the bottom surface opposite to the light receiving surface of the housing 91. Furthermore, the cable 80 is laid along the side surface of the housing 91 and does not bulge out sideways to avoid getting entangled with external matter.

Furthermore, the cable 80 is sandwiched securely between the fixing portion 36 of the cover 13 and the cable receiving portion 23 as the cover 13 is mounted on the box main body 12. Therefore, a dedicated fixing member for fixing the cable 80 is not required, and the entire configuration can be simplified and the number of parts can be reduced.

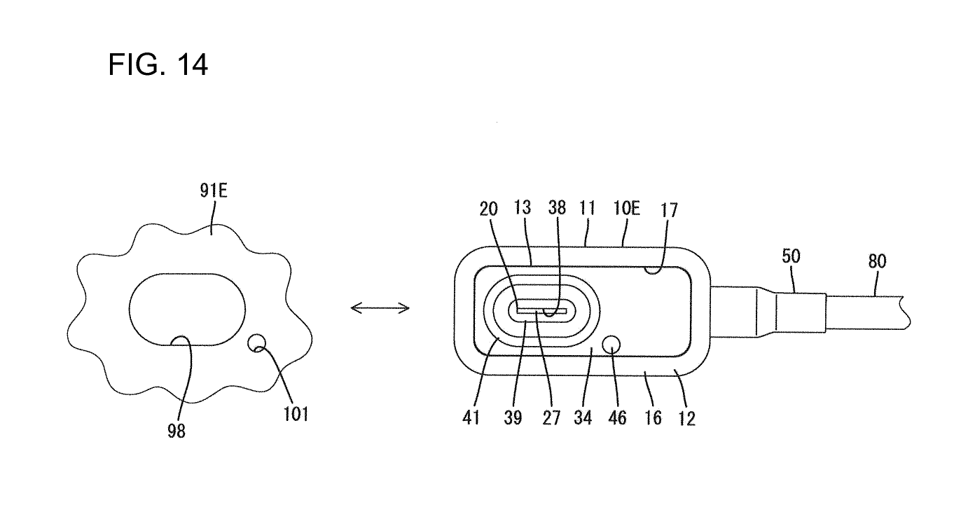

A second embodiment is shown in FIGS. 14 to 16 and is structured to prevent a plus-side terminal box 10E and a minus-side terminal box 10F from being mounted erroneously on housings 91E, 91E. The second embodiment is similar to the first embodiment except for an erroneous assembling preventing structure. Thus, the same components as the first embodiment are denoted by the same reference signs and are not described again.

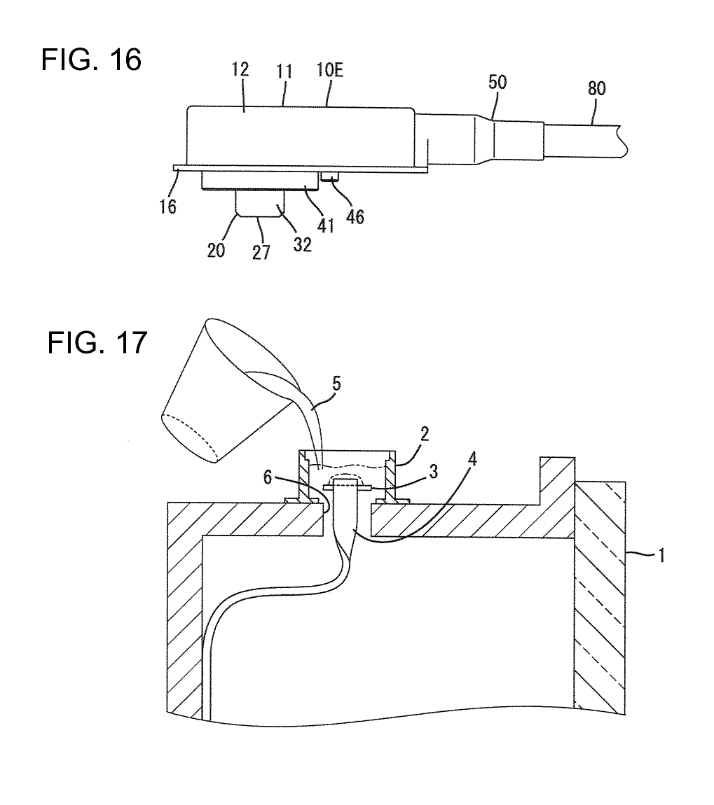

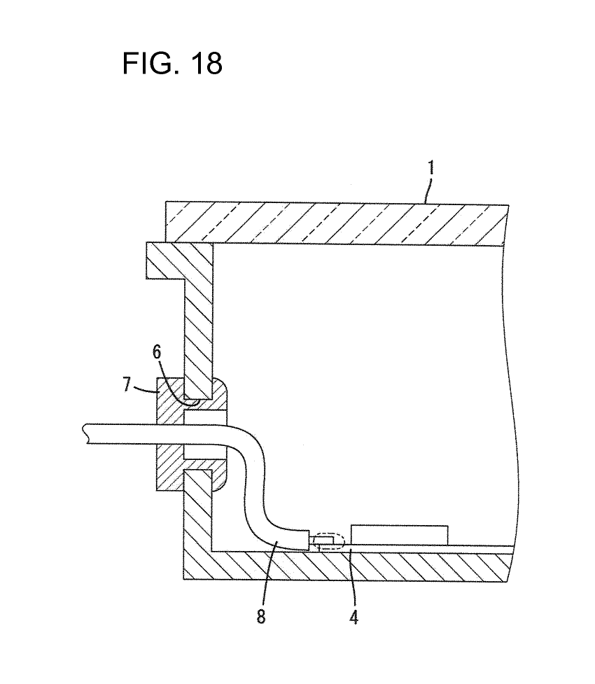

As shown in FIGS. 14 and 16, a plus-side identifying cylinder 46 projects from the front of a cover 13 of the plus-side terminal box 10E at a position displaced eccentrically to one side of the center of the front surface of a box 11. Further, a plus-side identification receiving circular hole 101 is formed on a side surface of the housing 91E to receive the plus-side identifying portion 46 when the box 11 is mounted. The plus-side identification receiving portion 101 is displaced eccentrically on one side of the side surface of the housing 91E across the center of an opening 98.

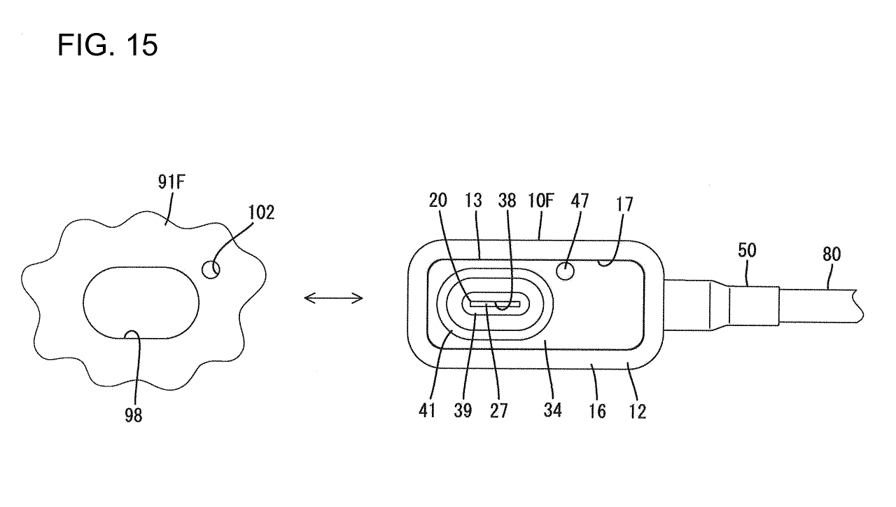

On the other hand, as shown in FIG. 15, a minus-side identifying cylinder 47 projects from the front of a cover 13 of the minus-side terminal box 10F. The minus-side identifying cylinder 47 is displaced eccentrically on the other side from the center of the front surface of the box 11. Further, a minus-side identification receiving circular hole 102 is formed on a side surface of the housing 91F and can receive the minus-side identifying portion 47 when the box 11 is mounted. The minus-side identification receiving portion 102 is arranged eccentrically on the other side of the side surface of the housing 91F across the center of an opening 98.

The plus-side identifying portion 46 can fit into the plus-side identification receiving portion 101 of the housing 91E, but cannot fit into the minus-side identification receiving portion 102 of the housing 91F when the terminal box 10E is mounted on the housing 91E. The minus-side identifying portion 47 can fit into the minus-side identification receiving portion 102 of the housing 91F, but cannot fit into the plus-side identification receiving portion 101 of the housing 91E when the terminal box 11F is mounted on the housing 91F. Thus, the plus-side terminal box 10E cannot be connected to a minus-side electrode by mistake and the minus-side terminal box 10F cannot be connected to a plus-side electrode by mistake.

The invention is not limited to the above described and embodiments. For example, the following embodiments also are included in the scope of the invention.

The cover may be mounted on the box main body after the sealing material such as silicon resin is poured into the box main body.

The plus-side and minus-side terminals may be arranged in parallel in the same box.

The cable and the terminal may be connected by soldering.

The plus-side identifying portion and the minus-side identifying portion of the second embodiment may be insulating portions having different shapes and the plus-side identification receiving portion and the minus-side identification receiving portion may be openings having different shapes.

The invention is also applicable to a thin-film power generation system composed of solar cell modules in a planar array, such as on the roof of a housing.

What is claimed is:

1. A terminal box (10) for solar cell module, comprising:
a box (11) made of resin and to be mounted on a housing (90) of a solar cell module;
a cable (80) for external connection, the cable (80) having an end part introduced into the box (11); and
a terminal (20) accommodated in the box (11) and including a cable connecting portion (26) to be connected to the cable (80) and a cell-side connecting portion (28) extending from the cable connecting portion (26), the cell-side connecting portion (28) being located outside the box (11) and insertable through an opening (98) in the housing (90) for connection to an electrode of solar cells (95) in the housing (90).

2. The terminal box (10) for solar cell module of claim 1, wherein the box (11) includes an insulating portion (41) to be located between the terminal (20) and the housing (90) in the opening (98) when the box (11) is mounted on the housing (90).

3. The terminal box (10) for solar cell module of claim 2, wherein the insulating portion (41) is configured for positioning the box (11) with respect to the housing (90) by being fit into the opening (98).

4. The terminal box (10) for solar cell module of claim 1, further comprising a plus-side terminal box (10A) whose conductor is to be connected to a plus-side electrode of the solar cells (95) and a minus-side terminal box (10B) whose conductor is to be connected to a minus-side electrode of the solar cells (95), wherein the plus-side terminal box (10A) and the minus-side terminal box (10B) are provided independently.

5. The terminal box (10) of claim 4, wherein the plus-side terminal box (10A) includes a plus-side identifying portion (46), the minus-side terminal box includes a minus-side identifying portion (47), the plus-side identifying portion (46) is engageable with a plus-side identification receiving portion (101) of the housing (90), but not engageable with a minus-side identification receiving portion (102) of the housing (90) when the plus-side terminal box (10A) is mounted on the housing (90), and the minus-side identifying portion (47) is engageable with the minus-side identification receiving portion (102) of the housing (90), but not engageable with the plus-side identification receiving portion (101) of the housing (90) when the minus-side terminal box (10B) is mounted on the housing (90).

6. The terminal box (10) for solar cell module of claim 1, wherein the box (11) is mounted on a side surface (97) intersecting with a light receiving surface of the housing (90).

7. The terminal box (10) for solar cell module of claim 6, wherein the cable (80) is laid along the side surface (97) of the housing (90).

8. The terminal box (10) for solar cell module of claim 1, wherein the box (11) includes a box main body (12) into which an end part of the cable (80) and the terminal (20) are accommodated and a cover (13) that is mounted on the box main body (12) to close an opening of the box main body (12), and the cover (13) is integrally provided with a fixing portion (36) for fixing the cable (80) by coming into contact with the cable (80) as the cover (13) is mounted on the box main body (11).
